(19) United States
(12) Patent Application Publication
(10) Pub. No.: US 2009/0086394 A1
(43) Pub. Date: Apr. 2, 2009

(54) PROTECTION CIRCUIT AND SEMICONDUCTOR INTEGRATED CIRCUIT

(76) Inventors: Eiji Yasuda, Osaka (JP); Tadayoshi Nakatsuka, Hyogo (JP)

Correspondence Address: MCDERMOTT WILL & EMERY LLP, 600 13TH STREET, NW, WASHINGTON, DC, 20005-3096, US

(21) Appl. No.: 12/237,066

(22) Filed: Sep. 24, 2008

(30) Foreign Application Priority Data
Sep. 27, 2007 (JP) 2007-251542

(51) Int. Cl. H02H 9/04; H01L 27/06

(52) U.S. Cl. 361/56; 257/296; 257/355; 257/E27.016

(57) ABSTRACT

In a circuit in which a protected element 42 is connected between an input terminal 61 and an output terminal 62, and a protected element 41 is connected between the input terminal 61 and a reference potential terminal 71, the protected element 41 and a protection circuit 51 are connected in parallel with each other. The protection circuit 51 includes: a field-effect transistor (FET) 11 having a drain connected to the input terminal 61 and a source connected to the reference potential terminal 71; a resistance 31 having one end connected to a gate of the FET 11; a resistance 32 for connecting the other end of the resistance 31 to the source of the FET 11; and a capacitor 21 for connecting the other end of the resistance 31 to the drain of the FET 11.

### BACKGROUND OF THE INVENTION

1. Field of the Invention

The present invention relates to a protection circuit for preventing electrostatic breakdown, and a semiconductor integrated circuit including the protection circuit.

2. Description of the Background Art

In recent years, a mobile communication apparatus has its size reduced and its performance enhanced, and therefore a radio frequency semiconductor device having enhanced performance is strongly required. In general, however, a radio frequency semiconductor device needs to trade off improvement of breakdown voltage of a transistor thereof for enhancement of its performance, so that its weakness in electrical stress from the outside, in particular, its weakness in electrostatic discharge (ESD), is increased. Accordingly, it is suggested that a technique using an enhancement-mode transistor is applied to a protection circuit so as to cope with the ESD.

FIG. 7 is a diagram illustrating a configuration of a semiconductor integrated circuit 100 including a conventional protection circuit 150 for coping with the ESD by using an enhancement-mode transistor.

As shown in FIG. 7, a protected element 110 such as a radio frequency circuit is connected to a terminal (electrode pad) 120 which is electrically connected to the outside via a lead wire. The terminal 120 is used as a digital signal terminal, an analog signal terminal, a power supply terminal, a grounding terminal, or the like. A drain of a transistor 130 is connected to the terminal 120, a gate thereof is grounded through a resistance 140, and a source thereof is directly grounded. The transistor 130 and the resistance 140 forms the protection circuit 150 for suppressing ESD voltage applied to the protected element 110 through the terminal 120 due to static electricity.

Hereinafter, an operation principle of the conventional protection circuit 150 using an enhancement-mode field-effect transistor as the transistor 130 will be described as an example.

When positive ESD voltage (high voltage pulse or the like) is applied to the terminal 120, drain voltage is increased in the transistor 130. At this time, gate voltage is also increased in the transistor 130 due to a leakage current leaking between the drain and the gate, and the resistance 140 being provided. When the gate voltage is increased so as to be greater than a threshold voltage set for the transmitter 130, the transistor 130 is in a conducting state, and the charge for ESD is discharged from the drain of the transmitter 130 to the source thereof. On the other hand, when negative ESD voltage (surge pulse or the like) is applied to the terminal 120, drain voltage is reduced in the transmitter 130. At this time, when the drain voltage is reduced so as to be lower than or equal to the threshold voltage set for the transistor 130, the transistor 130 is in a conducting state, and the charge for ESD is discharged from the source of the transistor 130 to the drain thereof.

When the threshold voltage for the transistor 130 and a resistance value of the resistance 140 are appropriately set, the transistor 130 can be in the conducting state before the drain voltage of the transistor 130 reaches breakdown voltage of the protected element 110, thereby preventing the protected element 110 from being broken down due to the ESD voltage.

However, the conventional semiconductor integrated circuit 100 shown in FIG. 7 needs some time period until the protection circuit 150 starts to operate after application of the ESD voltage to the terminal 120. The reason therefor is as follows. When the ESD voltage is applied to the terminal 120, reverse leakage current is initially generated between the drain and the gate in the transistor 130. The reverse leakage current flowing through the resistance 140 causes generation of a voltage. When the generated voltage becomes greater than the threshold voltage set for the transistor 130, a channel of the transistor 130 is on. Thus, some time period is needed until the transistor 130 causes the ESD current to bypass the protected element.

Therefore, when excessively high voltage is applied to the terminal 120 in a substantially short time period, a problem arises that the excessively high voltage may break down the protected element 110 before the protection circuit 150 operates.

### SUMMARY OF THE INVENTION

Therefore, an object of the present invention is to provide a protection circuit capable of shortening a time period required from application of the ESD voltage to start of the operation of the protection circuit, and improving the resistance of voltage to ESD.

The present invention is directed to a protection circuit connected to a protected element. In order to attain the object mentioned above, the protection circuit of the present invention uses a basic circuit including: an enhancement-mode field-effect transistor; a first resistance having one end connected to a gate of the field-effect transistor; a second resistance for connecting the other end of the first resistance to a source of the field-effect transmitter; and a capacitor for connecting the other end of the first resistance to a drain of the field-effect transistor, so as to realize various circuit configurations.

When the number of the basic circuits used is one, one of the drain and the source of the field-effect transistor is connected to the protected element, and the other of the drain and the source thereof is connected to a reference potential.

When the number of the basic circuits used is two, one of the drains of the two field-effect transistors is connected to the protected element, and the other of the drains thereof is connected to a reference potential, and the sources of the two field-effect transistors are connected to each other. Alternatively, when the number of the basic circuits used is two, one of the sources of the two field-effect transistors is connected to the protected element, and the other of the sources thereof is connected to a reference potential, and the drains of the two field-effect transistors are connected to each other.

Further, another basic circuit including: a first enhancement-mode field-effect transistor; a second field-effect transistor having a drain connected to a source of the first field-effect transistor; a first resistance having one end connected to a gate of the first field-effect transistor; a second resistance having one end connected to a gate of the second field-effect transistor; a third resistance for connecting the other end of the first resistance to the other end of the second resistance; a fourth resistance for connecting the other end of the second resistance to a source of the second field-effect transistor; and a capacitor for connecting the other end of the first resistance to a drain of the first field-effect transistor, may be used.

When the number of the another basic circuits used is one, one of the drain of the first field-effect transistor and the source of the second field-effect transistor is connected to the protected element, and the other of the drain of the first field-effect transistor and the source of the second field-effect transistor is connected to a reference potential.

When the number of the another basic circuits used is two, one of the drains of the two first field-effect transistors is connected to the protected element, and the other of the drains thereof is connected to a reference potential, and the sources of the two second field-effect transistors are connected to each other. Alternatively, when the number of the another basic circuits used is two, one of the sources of the two second field-effect transistors is connected to the protected element, and the other of the sources thereof is connected to a reference potential, and the drains of the two first field-effect transistors are connected to each other.

Typically, each of the various protections circuits described above and the protected element are formed on a same semiconductor substrate. In this case, it is preferable that the semiconductor substrate is a compound semiconductor substrate.

According to the present invention, a speed for responding to the ESD voltage applied to a protected element is enhanced, thereby enabling improvement of resistance of voltage to ESD.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram illustrating a configuration of a semiconductor integrated circuit 1 including a protection circuit 51 according to a first embodiment of the present invention;

FIG. 2 is a diagram illustrating a configuration of a semiconductor integrated circuit 2 including a protection circuit 52 according to a second embodiment of the present invention;

FIG. 3 is a diagram illustrating a configuration of a semiconductor integrated circuit 3 including a protection circuit 53 according to a third embodiment of the present invention;

FIG. 4 is a diagram illustrating a configuration of a semiconductor integrated circuit 4 including a protection circuit 54 according to a fourth embodiment of the present invention;

FIG. 5 is a diagram illustrating a configuration of a semiconductor integrated circuit 5 including a protection circuit 55 according to a fifth embodiment of the present invention;

FIG. 6 is a diagram illustrating a configuration of a semiconductor integrated circuit 6 including a protection circuit 56 according to a sixth embodiment of the present invention; and

FIG. 7 is a diagram illustrating a configuration of a semiconductor integrated circuit 100 including a conventional protection circuit 150.

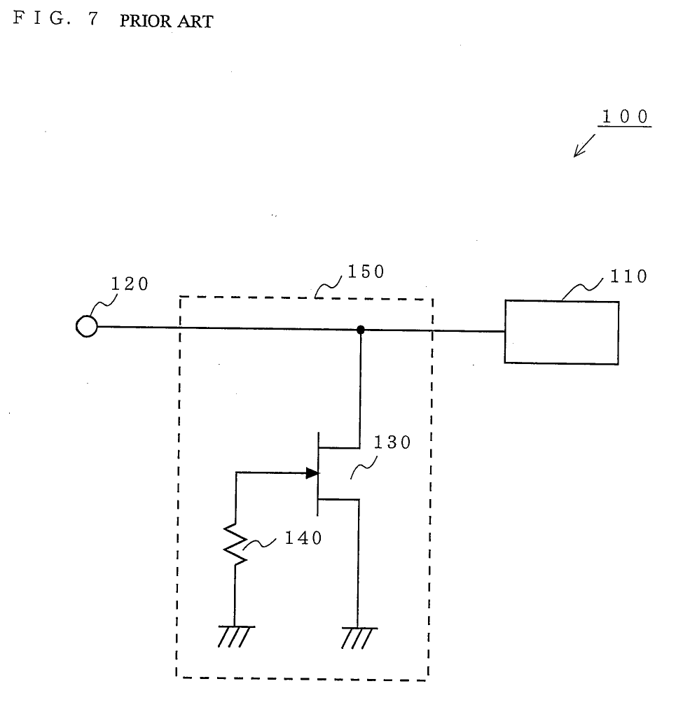

### DESCRIPTION OF THE PREFERRED EMBODIMENTS

Hereinafter, a protection circuit of the present invention will be described with reference to the drawings. In the following description, for example, an enhancement-mode MIS field-effect transistor, an enhancement-mode MES field-effect transistor, an enhancement-mode heterojunction field-effect transistor, or the like is used. However, also when a heterojunction bipolar transistor or the like is used, the same effect is obtained. In this case, a drain, a gate, and a source used in each embodiment are replaced with a collector, a base, and an emitter, respectively. Further, the protection circuit of the present invention may be included in a logic circuit or an analog circuit using a junction field-effect transistor, or the like, or the protection circuit of the present invention and a protected element may be formed on a compound semiconductor substrate.

### First Embodiment

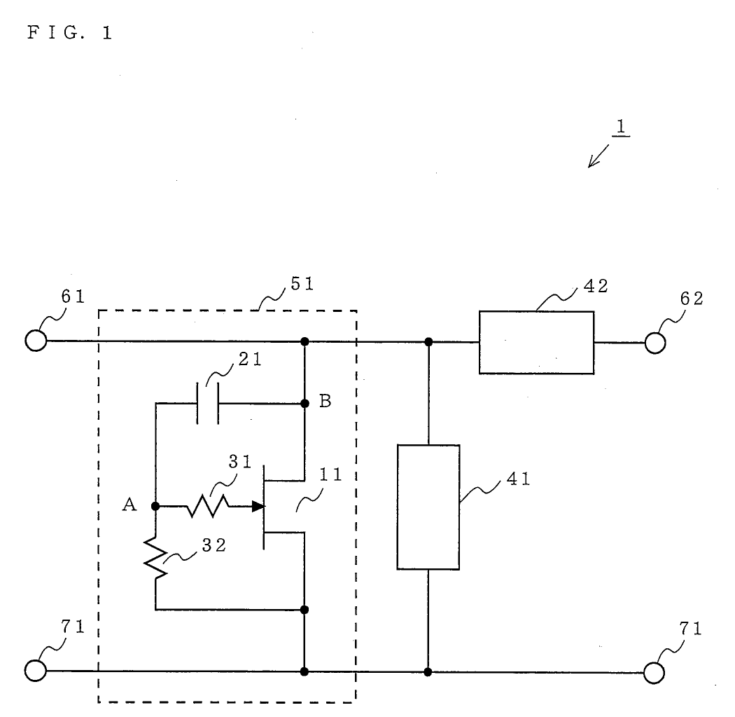

FIG. 1 is a diagram illustrating a configuration of a semiconductor integrated circuit 1 including a protection circuit 51 according to a first embodiment of the present invention. The semiconductor integrated circuit 1 according to the first embodiment is configured such that a protected element 42 is connected between an input terminal 61 and an output terminal 62, and a protected element 41 and the protection circuit 51 are connected in parallel with each other between the input terminal 61 and a reference potential terminal 71. The protection circuit 51 includes: a field-effect transistor (FET) 11 in which a drain thereof is connected to the input terminal 61, and a source thereof is connected to the reference potential terminal 71; a resistance 31 having one end connected to a gate of the FET 11; a resistance 32 for connecting the other end of the resistance 31 to the source of the FET 11; and a capacitor 21 for connecting the other end of the resistance 31 to the drain of the FET 11.

In FIG. 1, when no voltage is applied to the input terminal 61, voltage between the gate and the source of the FET 11 is 0V. When positive ESD voltage is applied to the input terminal 61, drain voltage is increased in the FET 11. At this time, at point A at which one of electrode ends of the capacitor 21 is connected to the resistance 31, voltage is instantly increased in accordance with voltage changing at point B at which the other of the electrode ends of the capacitor 21 is connected to the drain of the FET 11. That is, gate voltage is instantly increased in the FET 11. When a voltage between the gate and the source is greater than a threshold voltage set for the FET 11, the FET 11 is in a conducting state, and charge for ESD is discharged from the drain of the FET 11 to the source thereof, and the positive ESD voltage applied to each of the protected elements 41 and 42 is reduced. The resistance 31 functions to protect the gate of the FET 11, and prevents breakdown of the FET 11 due to gate forward current.

When negative ESD voltage is applied to the input terminal 61, the FET 11 acts as a diode. Thus, charge for ESD is discharged from the source of the FET 11 to the drain thereof, so that the negative ESD voltage applied to each of the protected elements 41 and 42 is reduced.

As described above, the protection circuit 51 according to the first embodiment of the present invention enables enhancement of speed for responding to the ESD voltage applied to each of the protected elements 41 and 42 so as to improve the resistance of voltage to ESD, thereby preventing breakdown of each of the protected elements 41 and 42.

### Second Embodiment

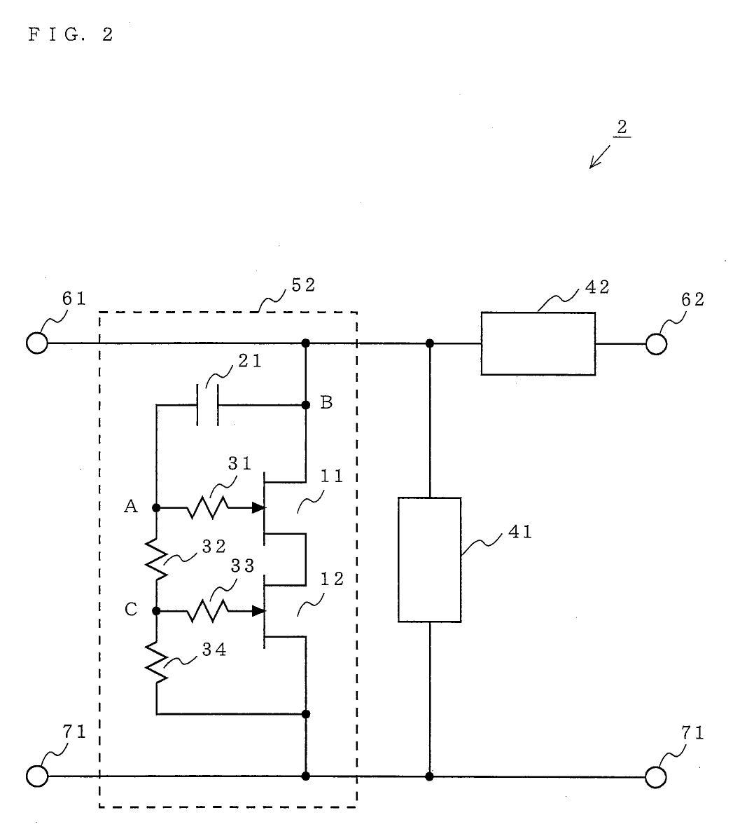

FIG. 2 is a diagram illustrating a configuration of a semiconductor integrated circuit 2 including a protection circuit 52 according to a second embodiment of the present invention. The semiconductor integrated circuit 2 according to the second embodiment is configured such that the protected element 42 is connected between the input terminal 61 and the output terminal 62, and the protected element 41 and the protection circuit 52 are connected in parallel with each other between the input terminal 61 and the reference potential terminal 71. The protection circuit 52 includes: the FET 11 in which the drain thereof is connected to the input terminal 61; a FET 12 in which a drain thereof is connected to the source of the FET 11, and a source thereof is connected to the reference potential terminal 71; the resistance 31 having one end connected to the gate of the FET 11; a resistance 33 having one end connected to a gate of the FET 12; the resistance 32 for connecting the other end of the resistance 31 to the other end of the resistance 33; a resistance 34 for connecting the other end of the resistance 33 to the source of the FET 12; and the capacitor 21 for connecting the other end of the resistance 31 to the drain of the FET 11.

In FIG. 2, when no voltage is applied to the input terminal 61, voltage between the gate and the source of the FET 11 is 0V. When positive ESD voltage is applied to the input terminal 61, drain voltage is increased in the FET 11. At this time, at points A and C at which one of electrode ends of the capacitor 21 is connected to the resistance 31, voltage is instantly increased in accordance with voltage changing at point B at which the other of the electrode ends of the capacitor 21 is connected to the drain of the FET 11. That is, gate voltages of the FET 11 and the FET 12 are instantly increased.

A ratio in voltage increase between point A and point C depends on a ratio in resistance value between the resistance 32 and the resistance 34, and determines a ratio at which the ESD voltage is divided between the drain/source of the FET 11 and the drain/source of the FET 12. When a voltage between the gate and the source of the FET 11 and a voltage between the gate and the source of the FET 12 are greater than threshold voltages, respectively, the FET 11 and the FET 12 are each in a conducting state, and charge for ESD is discharged from the drain of the FET 11 to the source of the FET 12, and the positive ESD voltage applied to each of the protected elements 41 and 42 is reduced. At this time, the ESD voltage is divided between the drain/source of the FET 11 and the drain/source of the FET 12, and therefore it is possible to prevent breakdown caused by the ESD voltage. The resistances 31 and 33 function to protect the gates, respectively, and prevent breakdowns of the FET 11 and the FET 12, respectively, caused due to gate forward current.

When negative ESD voltage is applied to the input terminal 61, the FET 11 and the FET 12 each act as a diode. Thus, charge for ESD is discharged from the source of the FET 12 to the drain of the FET 11, and the negative ESD voltage applied to each of the protected elements 41 and 42 is reduced.

As described above, the protection circuit 52 according to the second embodiment of the present invention enables enhancement of speed for responding to the ESD voltage applied to each of the protected elements 41 and 42 so as to improve the resistance of voltage to ESD, thereby preventing breakdown of each of the protected elements 41 and 42. Further, the ESD voltage applied to each of the protected elements 41 and 42 is divided between the FET 11 and the FET 12, thereby preventing breakdown of each of the protected elements 41 and 42 even when the ESD voltage is further increased.

### Third Embodiment

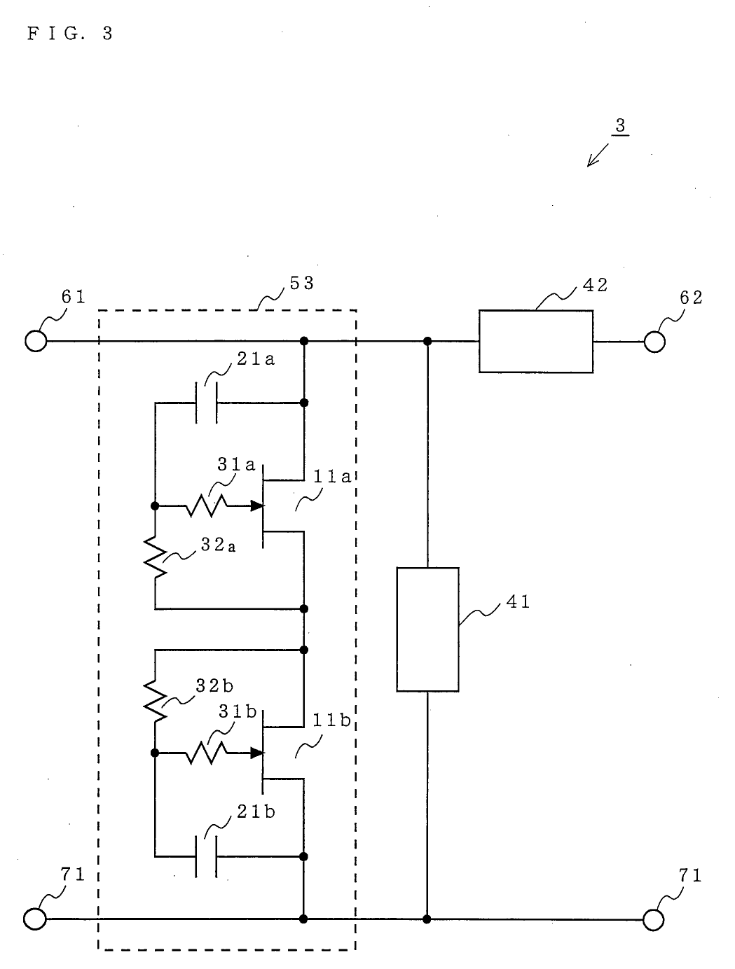

FIG. 3 is a diagram illustrating a configuration of a semiconductor integrated circuit 3 including a protection circuit 53 according to a third embodiment of the present invention. The semiconductor integrated circuit 3 according to the third embodiment is configured such that the protected element 42 is connected between the input terminal 61 and the output terminal 62, and the protected element 41 and the protection circuit 53 are connected in parallel with each other between the input terminal 61 and the reference potential terminal 71. The protection circuit 53 has a configuration in which the two protection circuits 51 of the first embodiment are connected in series with each other such that one of the two protection circuits 51 has the capacitor 21 connected to the input terminal 61, and the other of the two protection circuits 51 has the capacitor 21 connected to the reference potential terminal 71 so as to position the two protection circuits 51 in a symmetrical manner.

When in the above configuration positive ESD voltage is applied to the input terminal 61, a FET 11a is in a conducting state, and a FET 11b acts as a diode. Therefore, charge for ESD is discharged from a drain of the FET 11a to a drain of the FET 11b, and the positive ESD voltage applied to each of the protected elements 41 and 42 is reduced. When negative ESD voltage is applied to the input terminal 61, the FET 11b is in a conducting state, and the FET 11a acts as a diode. Thus, charge for ESD is discharged from the drain of the FET 11b to the drain of the FET 11a, and the negative ESD voltage applied to each of the protected elements 41 and 42 is reduced.

As described above, the protection circuit 53 according to the third embodiment of the present invention enables enhancement of speed for responding to the ESD voltage applied to each of the protected elements 41 and 42 so as to improve the resistance of voltage to ESD, thereby preventing breakdown of each of the protected elements 41 and 42. Further, negative voltage which is lower than or equal to forward voltage of the gate of the FET 11a can be applied to the input terminal 61, and therefore an absolute value of positive voltage is equal to an absolute value of negative voltage, thereby enabling a wide range of applications of the protection circuit 53.

### Fourth Embodiment

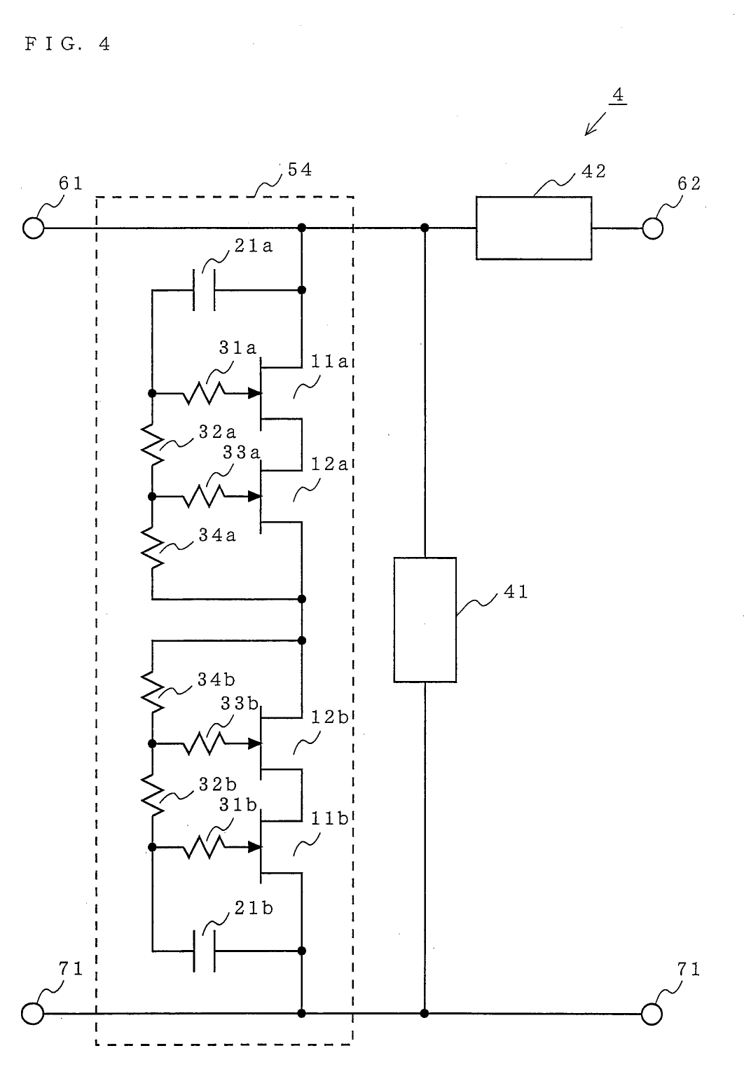

FIG. 4 is a diagram illustrating a configuration of a semiconductor integrated circuit 4 including a protection circuit 54 according to a fourth embodiment of the present invention. The semiconductor integrated circuit 4 according to the fourth embodiment is configured such that the protected element 42 is connected between the input terminal 61 and the output terminal 62, and the protected element 41 and the protection circuit 54 are connected in parallel with each other between the input terminal 61 and the reference potential terminal 71. The protection circuit 54 has a configuration in which the two protection circuits 52 of the second embodiment are connected in series with each other such that one of the two protection circuits 52 has the capacitor 21 connected to the input terminal 61, and the other of the two protection circuits 52 has the capacitor 21 connected to the reference potential terminal 71 so as to position the two protection circuits 52 in a symmetrical manner.

When in the above configuration positive ESD voltage is applied to the input terminal 61, the FET 11a and a FET 12a are each in a conducting state, and the FET 11b and a FET 12b each act as a diode. Therefore, charge for ESD is discharged from the drain of the FET 11a to the drain of the FET 11b, and positive ESD voltage applied to each of the protected elements 41 and 42 is reduced. When negative ESD voltage is applied to the input terminal 61, the FET 11b and the FET 12b are each in a conducting state, and the FET 11a and the FET 12a each act as a diode. Thus, charge for ESD is discharged from the drain of the FET lib to the drain of the FET 11a, and the negative ESD voltage applied to each of the protected elements 41 and 42 is reduced.

As described above, the protection circuit 54 according to the fourth embodiment of the present invention enables enhancement of speed for responding to the ESD voltage applied to each of the protected elements 41 and 42 so as to improve the resistance of voltage to ESD, thereby preventing breakdown of each of the protected elements 41 and 42. Further, the ESD voltage applied to each of the protected elements 41 and 42 is divided between the FET 11 and the FET 12, thereby preventing breakdown of each of the protected elements 41 and 42 even when the ESD voltage is further increased. Further, negative voltage which is lower than or equal to forward voltages of the gates of the FET 11a and the FET 12a can be applied to the input terminal 61, and therefore an absolute value of positive voltage is equal to an absolute value of negative voltage, thereby enabling a wide range of applications of the protection circuit 54. Further, the FETs are provided in multiple steps, and therefore the absolute values of the positive and the negative voltages can be increased so as to be greater values.

### Fifth Embodiment

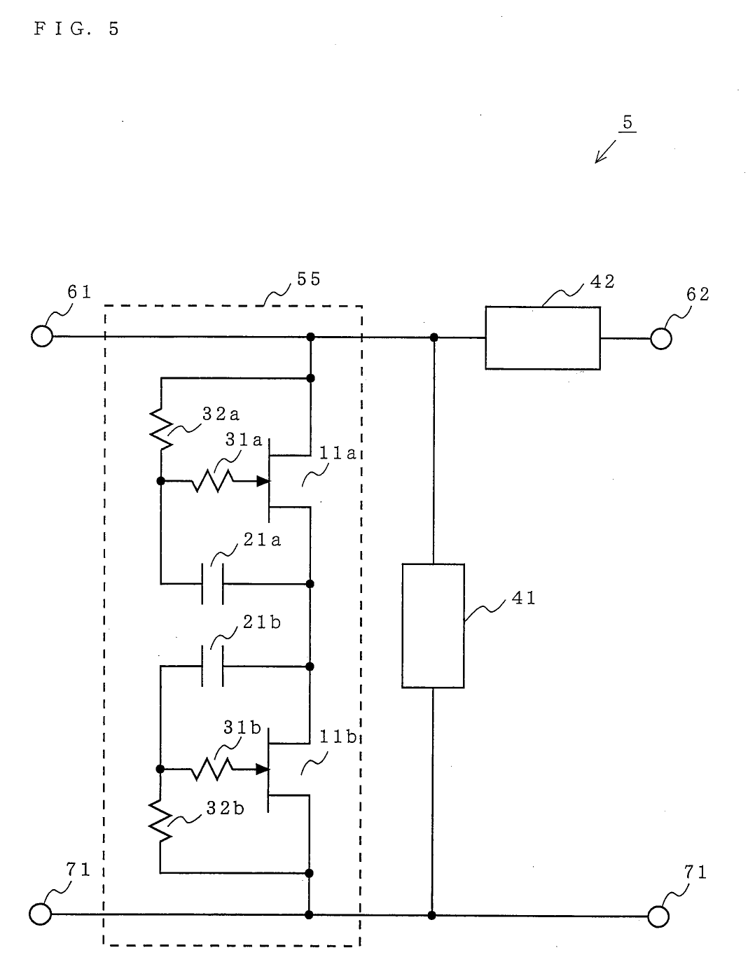

FIG. 5 is a diagram illustrating a configuration of a semiconductor integrated circuit 5 including a protection circuit 55 according to a fifth embodiment of the present invention. The semiconductor integrated circuit 5 according to the fifth embodiment is configured such that the protected element 42 is connected between the input terminal 61 and the output terminal 62, and the protected element 41 and the protection circuit 55 are connected in parallel with each other between the input terminal 61 and the reference potential terminal 71. The protection circuit 55 has a configuration in which the two protection circuits 51 of the first embodiment are connected in series with each other such that the capacitor 21 of one of the two protection circuits 51 is connected to the capacitor 21 of the other of the two protection circuits 51 so as to position the two protection circuits 51 in a symmetrical manner.

When in the above configuration positive ESD voltage is applied to the input terminal 61, the FET 11a acts as a diode and the FET 11b is in a conducting state, and therefore charge for ESD is discharged from the source of the FET 11a to the source of the FET 11b. Therefore, the positive ESD voltage applied to each of the protected elements 41 and 42 is reduced. When negative ESD voltage is applied to the input terminal 61, the FET 11b acts as a diode and the FET 11a is in a conducting state. Accordingly, charge for ESD is discharged from the source of the FET 11b to the source of the FET 11a, and therefore the negative ESD voltage applied to each of the protected elements 41 and 42 is reduced.

As described above, the protection circuit 55 according to the fifth embodiment of the present invention exerts the same effect as described for the third embodiment.

### Sixth Embodiment

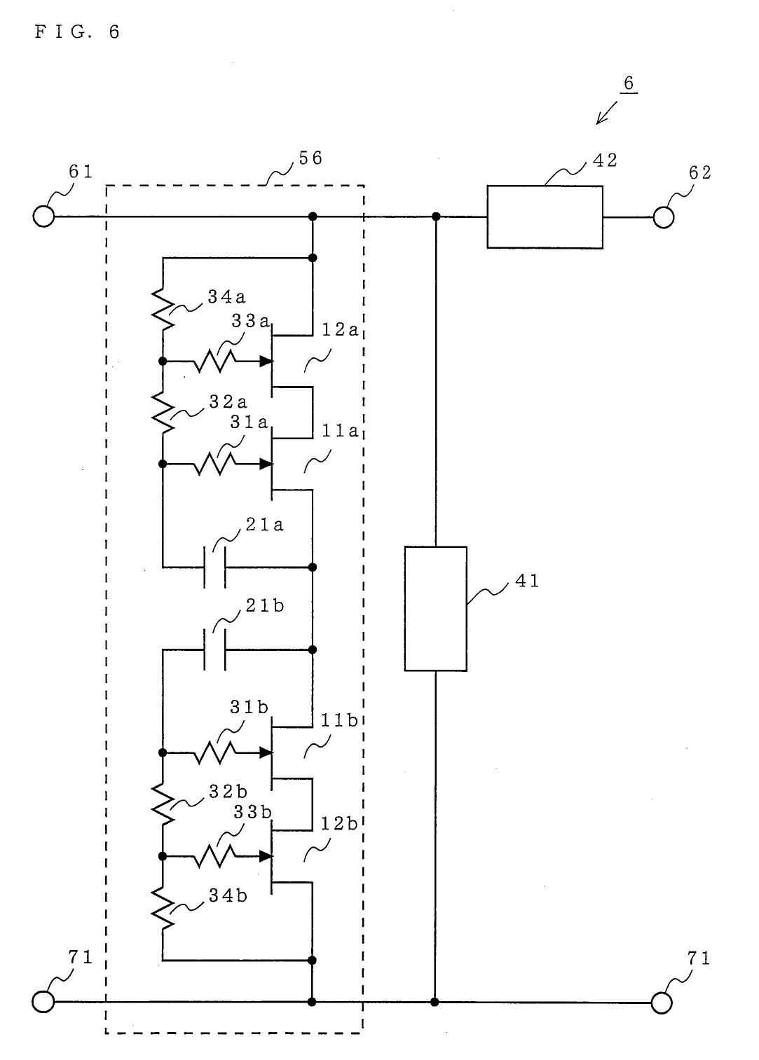

FIG. 6 is a diagram illustrating a configuration of a semiconductor integrated circuit 6 including a protection circuit 56 according to a sixth embodiment of the present invention. The semiconductor integrated circuit 6 according to the sixth embodiment is configured such that the protected element 42 is connected between the input terminal 61 and the output terminal 62, and the protected element 41 and the protection circuit 56 are connected in parallel with each other between the input terminal 61 and the reference potential terminal 71. The protection circuit 56 has a configuration in which the two protection circuits 52 of the second embodiment are connected in series with each other such that the capacitor 21 of one of the two protection circuits 52 is connected to the capacitor 21 of the other of the two protection circuits 52 so as to position the two protection circuits 52 in a symmetrical manner.

When in the above configuration positive ESD voltage is applied to the input terminal 61, the FET 11a and the FET 12a each act as a diode and the FET 11b and the FET 12b are each in a conducting state, and therefore charge for ESD is discharged from the source of the FET 12a to the source of the FET 12b. Therefore, the positive ESD voltage applied to each of the protected elements 41 and 42 is reduced. When negative ESD voltage is applied to the input terminal 61, the FET 11b and the FET 12b each act as a diode and the FET 11a and the FET 12a are each in a conducting state, and therefore charge for ESD is discharged from the source of the FET 12b to the source of the FET 12a. Therefore, the negative ESD voltage applied to each of the protected elements 41 and 42 is reduced.

As described above, the protection circuit 56 according to the sixth embodiment of the present invention exerts the same effect as described for the fourth embodiment.

While the invention has been described in detail, the foregoing description is in all aspects illustrative and not restrictive. It is understood that numerous other modifications and variations can be devised without departing from the scope of the invention.

1. A protection circuit connected to a protected element, comprising:
an enhancement-mode field-effect transistor;
a first resistance having one end connected to a gate of the field-effect transistor;
a second resistance for connecting the other end of the first resistance to a source of the field-effect transmitter; and
a capacitor for connecting the other end of the first resistance to a drain of the field-effect transistor,
wherein one of the drain and the source of the field-effect transistor is connected to the protected element, and the other of the drain and the source thereof is connected to a reference potential.

2. A protection circuit connected to a protected element, comprising:
a first enhancement-mode field-effect transistor;
a second field-effect transistor having a drain connected to a source of the first field-effect transistor;
a first resistance having one end connected to a gate of the first field-effect transistor;
a second resistance having one end connected to a gate of the second field-effect transistor;
a third resistance for connecting the other end of the first resistance to the other end of the second resistance;
a fourth resistance for connecting the other end of the second resistance to a source of the second field-effect transistor; and
a capacitor for connecting the other end of the first resistance to a drain of the first field-effect transistor,
wherein one of the drain of the first field-effect transistor and the source of the second field-effect transistor is connected to the protected element, and the other of the drain of the first field-effect transistor and the source of the second field-effect transistor is connected to a reference potential.

3. A protection circuit connected to a protected element, comprising:
a first enhancement-mode field-effect transistor;
a first resistance having one end connected to a gate of the first field-effect transistor;
a second resistance for connecting the other end of the first resistance to a source of the first field-effect transistor;
a first capacitor for connecting the other end of the first resistance to a drain of the first field-effect transistor;
a second enhancement-mode field-effect transistor;
a third resistance having one end connected to a gate of the second field-effect transistor;
a fourth resistance for connecting the other end of the third resistance to a source of the second field-effect transistor; and
a second capacitor for connecting the other end of the third resistance to a drain of the second field-effect transistor,
wherein one of the drains of the first field-effect transistor and the second field-effect transistor is connected to the protected element, and the other of the drains thereof is connected to a reference potential, and the sources of the first field-effect transistor and the second field-effect transistor are connected to each other.

4. A protection circuit connected to a protected element, comprising:
a first enhancement-mode field-effect transistor;
a second field-effect transistor having a drain connected to a source of the first field-effect transistor;
a first resistance having one end connected to a gate of the first field-effect transistor;
a second resistance having one end connected to a gate of the second field-effect transistor;
a third resistance for connecting the other end of the first resistance to the other end of the second resistance;
a fourth resistance for connecting the other end of the second resistance to a source of the second field-effect transistor;
a first capacitor for connecting the other end of the first resistance to a drain of the first field-effect transistor;
a third enhancement-mode field-effect transistor;
a fourth field-effect transistor having a drain connected to a source of the third field-effect transistor;
a fifth resistance having one end connected to a gate of the third field-effect transistor;
a sixth resistance having one end connected to a gate of the fourth field-effect transistor;
a seventh resistance for connecting the other end of the fifth resistance to the other end of the sixth resistance;
an eighth resistance for connecting the other end of the sixth resistance to a source of the fourth field-effect transistor; and
a second capacitor for connecting the other end of the fifth resistance to a drain of the third field-effect transistor; and
wherein one of the drains of the first field-effect transistor and the third field-effect transistor is connected to the protected element, and the other of the drains thereof is connected to a reference potential, and the sources of the second field-effect transistor and the fourth field-effect transistor are connected to each other.

5. A protection circuit connected to a protected element, comprising:
a first enhancement-mode field-effect transistor;
a first resistance having one end connected to a gate of the first field-effect transistor;
a second resistance for connecting the other end of the first resistance to a source of the first field-effect transistor;
a first capacitor for connecting the other end of the first resistance to a drain of the first field-effect transistor;
a second enhancement-mode field-effect transistor;
a third resistance having one end connected to a gate of the second field-effect transistor;
a fourth resistance for connecting the other end of the third resistance to a source of the second field-effect transistor; and
a second capacitor for connecting the other end of the third resistance to a drain of the second field-effect transistor,
wherein one of the sources of the first field-effect transistor and the second field-effect transistor is connected to the protected element, and the other of the sources thereof is connected to a reference potential, and the drains of the first field-effect transistor and the second field-effect transistor are connected to each other.

6. A protection circuit connected to a protected element, comprising:
a first enhancement-mode field-effect transistor;
a second field-effect transistor having a drain connected to a source of the first field-effect transistor;
a first resistance having one end connected to a gate of the first field-effect transistor;
a second resistance having one end connected to a gate of the second field-effect transistor;
a third resistance for connecting the other end of the first resistance to the other end of the second resistance;
a fourth resistance for connecting the other end of the second resistance to a source of the second field-effect transistor;
a first capacitor for connecting the other end of the first resistance to a drain of the first field-effect transistor;
a third enhancement-mode field-effect transistor;
a fourth field-effect transistor having a drain connected to a source of the third field-effect transistor;
a fifth resistance having one end connected to a gate of the third field-effect transistor;
a sixth resistance having one end connected to a gate of the fourth field-effect transistor;
a seventh resistance for connecting the other end of the fifth resistance to the other end of the sixth resistance;
an eighth resistance for connecting the other end of the sixth resistance to a source of the fourth field-effect transistor; and
a second capacitor for connecting the other end of the fifth resistance to a drain of the third field-effect transistor;
wherein one of the sources of the second field-effect transistor and the fourth field-effect transistor is connected to the protected element, and the other of the sources thereof is connected to a reference potential, and the drains of the first field-effect transistor and the third field-effect transistor are connected to each other.

7. A semiconductor integrated circuit, wherein the protection circuit according to claim 1 and the protected element are formed on a same semiconductor substrate.

8. The semiconductor integrated circuit according to claim 7, wherein the semiconductor substrate is a compound semiconductor substrate.

9. A semiconductor integrated circuit, wherein the protection circuit according to claim 2 and the protected element are formed on a same semiconductor substrate.

10. A semiconductor integrated circuit, wherein the protection circuit according to claim 3 and the protected element are formed on a same semiconductor substrate.

11. A semiconductor integrated circuit, wherein the protection circuit according to claim 4 and the protected element are formed on a same semiconductor substrate.

12. A semiconductor integrated circuit, wherein the protection circuit according to claim 5 and the protected element are formed on a same semiconductor substrate.

13. A semiconductor integrated circuit, wherein the protection circuit according to claim 6 and the protected element are formed on a same semiconductor substrate.
